(19) United States
(12) Patent Application Publication
(10) Pub. No.: US 2016/0365264 A1
(43) Pub. Date: Dec. 15, 2016

(54) SUBSTRATE PROCESSING APPARATUS

(71) Applicant: HITACHI KOKUSAI ELECTRIC INC., Tokyo (JP)

(72) Inventors: Akao TOKUNOBU, Toyama-shi (JP); Tomoshi TANIYAMA, Toyama-shi (JP)

(73) Assignee: HITACHI KOKUSAI ELECTRIC INC., Tokyo (JP)

(21) Appl. No.: 15/245,728

(22) Filed: Aug. 24, 2016

Related U.S. Application Data
(63) Continuation of application No. PCT/JP2015/054139, filed on Feb. 16, 2015.

(30) Foreign Application Priority Data
Feb. 24, 2014 (JP) 2014-032949

(51) Int. Cl. H01L 21/67; H01L 21/677; F27D 21/00; H01L 21/673

(52) U.S. Cl. CPC H01L 21/67288; H01L 21/67109; H01L 21/67389; H01L 21/67778; H01L 21/67772; H01L 21/67766; F27D 21/00; F27D 2021/0078

(57) ABSTRACT

The present invention provides a technique in which a reduction in yield rate caused by particles occurring in the processing furnace is suppressed. The technique includes a substrate processing apparatus comprising a transfer chamber including a gas supply mechanism on a side surface thereof and configured to transfer a substrate to a substrate holder, a processing furnace, a furnace opening, a cap having the substrate holder placed thereon and configured to close the furnace opening, a raising/lowering mechanism configured to raise and lower the cap, a measurer installed at a position facing the gas supply mechanism in the transfer chamber with the substrate holder interposed therebetween, and configured to count a number of particles at the furnace opening, and a control unit configured to control the raising/lowering mechanism and the measurer so as to start measurement of a number of particles by the measurer when the furnace opening is opened.

### TECHNICAL FIELD

The present invention relates to a substrate processing apparatus.

### RELATED ART

In general, in a substrate processing apparatus which is used in a semiconductor device manufacturing process, annealing and film formation are performed using processing gas, etc., in a processing furnace where wafers (substrates) are processed. Due to particles occurring along with these processes, degradation in film quality, lot rejection, etc., occur, causing a program of a reduction in the yield rate of device manufacturing. For a technique for suppressing such particles, there is, for example, a technique described in Patent Literature 1.

### CITATION LIST

### Patent Literature

Patent Literature 1: JP 2012-79907 A

### SUMMARY OF INVENTION

### Technical Problem

In the technique described in Patent Literature 1, however, although particles in a transfer chamber can be suppressed by purging the inside of the transfer chamber, when a large amount of particles occur in a processing furnace, degradation in film quality and lot rejection occur.

An object of the present invention is to provide a technique capable of monitoring conditions in a processing furnace and suppressing a reduction in yield rate caused by particles occurring in the processing furnace.

### Solution to Problem

According to an aspect of the present invention, there is provided a technology including: a transfer chamber including a gas supply mechanism on a side surface thereof and configured to transfer a substrate to a substrate holder; a processing furnace configured to process the substrate holded in the substrate holder; a furnace opening that communicates between the transfer chamber and the processing furnace; a cap having the substrate holder placed thereon and configured to close the furnace opening; a raising/lowering mechanism configured to raise and lower the cap; a measurer installed at a position facing the gas supply mechanism in the transfer chamber with the substrate holder interposed therebetween, and configured to count a number of particles at the furnace opening; and a control unit configured to control the raising/lowering mechanism and the measurer so as to start measurement of a number of particles by the measurer when the furnace opening is opened.

### Advantageous Effects of Invention

According to the present invention, conditions in a processing furnace can be monitored and a reduction in yield rate caused by particles occurring in the processing furnace can be suppressed.

### BRIEF DESCRIPTION OF DRAWINGS

FIG. 1 is a perspective view of a substrate processing apparatus which is favorably used in embodiments of the present invention.

FIG. 2 is a cross-sectional view of the substrate processing apparatus which is favorably used in the embodiments of the present invention.

FIG. 3 is a block diagram illustrating an example of a configuration of the substrate processing apparatus which is favorably used in the embodiments of the present invention, with a main controller being a core component.

FIG. 4 is a diagram illustrating measurement timing of a particle counter which is favorably used in the embodiments of the present invention.

FIG. 5 is a longitudinal cross-sectional view of a substrate processing apparatus according to a first embodiment of the present invention.

FIG. 6a is a transverse cross-sectional view of a substrate processing apparatus according to the first embodiment of the present invention.

FIG. 6b is a transverse cross-sectional view of a substrate processing apparatus according to the first embodiment of the present invention.

FIG. 7a is a transverse cross-sectional view of a substrate processing apparatus according to a second embodiment of the present invention.

FIG. 7b is a transverse cross-sectional view of a substrate processing apparatus according to the second embodiment of the present invention.

FIG. 7c is a transverse cross-sectional view of a substrate processing apparatus according to the second embodiment of the present invention.

### DESCRIPTION OF EMBODIMENTS

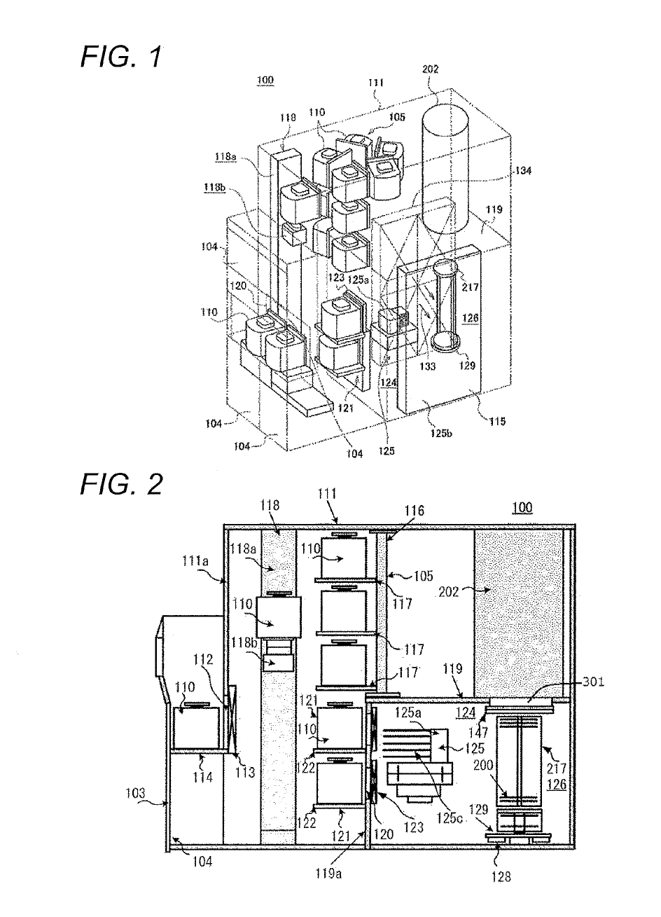

A mode for carrying out the present invention will be described below based on FIGS. 1 and 2.

A substrate processing apparatus 100 processes wafers 200 which are used as substrates and composed of silicon, etc.

As illustrated in FIGS. 1 and 2, the substrate processing apparatus 100 uses FOUPs (substrate containers; hereinafter, referred to as pods) 110 which are used as wafer carriers containing the wafers 200. In addition, the substrate processing apparatus 100 includes a substrate processing apparatus main body 111.

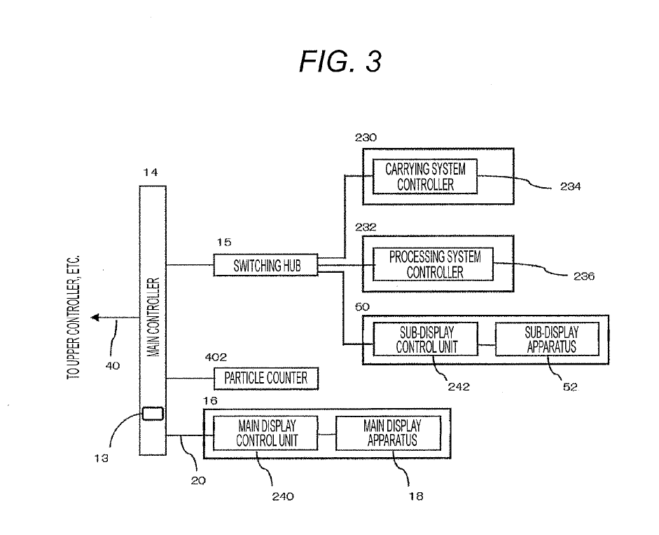

A front maintenance opening 103 which is used as an opening portion provided to allow maintenance is opened in a front forward portion of a front wall 111a of the substrate processing apparatus main body 111, and front maintenance doors 104 that open and close the front maintenance opening 103 are installed. Note that, though not illustrated, a sub-operating apparatus 50 serving as a sub-operating unit is installed near the front maintenance door 104 on the upper side. A main operating apparatus 16 serving as a main operating unit (see FIG. 3) is disposed near the maintenance door 104 on the back side.

A pod loading/unloading opening (substrate container loading/unloading opening) 112 is opened in the front wall 111a of the substrate processing apparatus main body 111 so as to communicate between the inside and outside of the substrate processing apparatus main body 111, and the pod loading/unloading opening 112 is opened and closed by a front shutter (substrate container loading/unloading opening's opening/closing mechanism) 113. A load port (substrate container passing table) 114 is installed on the front forward side of the pod loading/unloading opening 112, and the load port 114 is configured to place a pod 110 thereon for alignment. The pod 110 is loaded onto the load port 114 by an in-process carrying apparatus (not illustrated), and unloaded from the load port 114.

A pod shelf (substrate container placement shelf) 105 is installed in a top portion of a substantially central portion in a front-back direction of the substrate processing apparatus main body 111, and the pod shelf 105 is configured to store a plurality of pods 110.

A pod carrying apparatus (substrate container carrying apparatus) 118 is installed between the load port 114 and the pod shelf 105 in the substrate processing apparatus main body 111, and the pod carrying apparatus 118 is configured to carry a pod 110 between the load port 114, the pod shelf 105, and pod openers (substrate container cap opening/closing mechanisms) 121.

A sub-housing 119 is constructed in a bottom portion of the substantially central portion in the front-back direction of the substrate processing apparatus main body 111 over a rear end of the substrate processing apparatus main body 111. A pair of wafer loading/unloading openings (substrate loading/unlading openings) 120 for loading and unloading wafers 200 into/from the sub-housing 119 are opened in a front wall 119a of the sub-housing 119 in a vertical direction so as to be placed side by side at two levels, top and bottom. The pair of pod openers 121 and 121 are respectively installed for the wafer loading/unloading openings 120 and 120 at the top and bottom levels. The pod openers 121 include placement tables 122 and 122 where pods 110 are placed; and cap attachment/removal mechanisms (cap attachment/removal mechanisms) 123 and 123 that attach and remove caps of the pods 110. Each pod opener 121 is configured to open and close a wafer take-in/out opening of a pod 110 by attaching and removing a cap of the pod 110 placed on a corresponding placement table 122, by a corresponding cap attachment/removal mechanism 123.

The sub-housing 119 configures a transfer chamber 124 which is fluidly isolated from the installation space of the pod carrying apparatus 118 and the pod shelf 105. A wafer transfer mechanism (substrate transfer mechanism) 125 is installed in a front-side area of the transfer chamber 124, and the wafer transfer mechanism 125 is configured by a wafer transfer apparatus (substrate transfer apparatus) 125a that allows wafers 200 to rotate or linearly move in a horizontal direction; and a wafer transfer apparatus elevator (substrate transfer apparatus raising/lowering mechanism) 125b for raising and lowering the wafer transfer apparatus 125a. The wafer transfer apparatus elevator 125b is installed between a right-side edge portion of the substrate processing apparatus main body 111 and a forward area right edge portion of the transfer chamber 124 in the sub-housing 119. It is configured such that by continuous operation of the wafer transfer apparatus elevator 125b and the wafer transfer apparatus 125a, wafers 200 are charged and discharged into/from a boat (substrate holder) 217 with tweezers (substrate holding elements) 125c of the wafer transfer apparatus 125a serving as placement units for the wafers 200.

A standby unit 126 where the boat 217 is accommodated and put on standby is configured at a rear-side area of the transfer chamber 124. A processing furnace 202 having formed therein a processing chamber where substrates 200 are processed is provided above the standby unit 126. A lower end portion of the processing furnace 202 and the transfer chamber 124 communicate with each other by a furnace opening 301 which is an opening for loading and unloading the boat 217. The furnace opening 301 is configured to be opened and closed by a furnace opening shutter (furnace opening's opening/closing mechanism) 147.

A boat elevator (substrate holder raising/lowering mechanism) 115 for raising and lowering the boat 217 is installed between the right-side edge portion of the substrate processing apparatus main body 111 and a right edge portion of the standby unit 126 in the sub-housing 119. A seal cap 129 serving as a cap is mounted horizontally on an arm 128 which serves as a coupler coupled to an elevating table of the boat elevator 115, and the seal cap 129 is configured to support the boat 217 vertically and to be able to block (close) the lower end portion of the processing furnace 202.

The boat 217 includes a plurality of holders, and is configured to hold each of a plurality of (e.g., about 25 to 125) wafers 200 horizontally such that the wafers 200 are lined up in the vertical direction with their centers aligned.

In addition, a clean unit 134 serving as a gas supply mechanism that supplies gas into the transfer chamber 124 is installed at a left-side edge portion of the transfer chamber 124 that is on the opposite side of the wafer transfer apparatus elevator 125b side and the boat elevator 115 side. The gas supply mechanism is configured by a supply fan and a dustproof filter so as to supply clean air 133 which is cleaned atmosphere or gas such as inert gas. A notch matching apparatus serving as a substrate matching apparatus that allows the positions in a circumferential direction of wafers 200 to match each other may be installed between the wafer transfer apparatus 125a and the clean unit 134.

It is configured such that the clean air 133 blown from the clean unit 134 is distributed to the wafer transfer apparatus 125a and the boat 217 present in the standby unit 126, and then sucked by a duct (not illustrated) and exhausted outside the substrate processing apparatus main body 111, or circulated to a primary side (supply side) which is the sucking side of the clean unit 134, and blown back into the transfer chamber 124 by the clean unit 134.

As illustrated in FIG. 5, a space particle measurement opening (hereinafter, particle measurement opening) 400 which is a measurement opening for collecting particles for measurement is installed in the transfer chamber 124, and the particle measurement opening 400 is connected by a tube 401 to a space particle counter (hereinafter, particle counter) 402 which is a counter for counting particles. A particle measurer serving as a measurer that measures particles floating in space is configured by the particle measurement opening 400, the tube 401, and the particle counter 402. Furthermore, the particle counter 402 is connected to a main controller 14 described later.

Next, with reference to FIG. 3, a hardware configuration of the substrate processing apparatus 100 with the main controller 14 being a core component will be described. As illustrated in FIG. 3, the main controller 14 serving as a main control unit is connected to the main operating apparatus 16 serving as a main operating unit, using, for example, a video cable 20. Note that instead of connecting the main controller 14 to the main operating apparatus 16 using the video cable 20, the main controller 14 and the main operating apparatus 16 may be connected to each other through a communication network. In addition, the main controller 14 is connected to an external operating apparatus (not illustrated) through, for example, a communication network 40. Hence, the external operating apparatus can be disposed at a location away from the substrate processing apparatus 100. For example, the external operating apparatus can be disposed in an office, etc., outside a clean room where the substrate processing apparatus 100 is installed. The main controller 14 has, for example, an OS for a USB port installed thereon and thus an external memory device compatible with the USB port (e.g., a USB flash memory) can be inserted into the substrate processing apparatus 100. In addition, there is provided a port 13 serving as a placement/removal unit that places and removes a USB flash memory, etc., which is a recording medium serving as an external memory device.

The main controller 14 may be configured as a computer including a CPU (Central Processing Unit), a RAM (Random Access Memory), a memory device, and an I/O port. At this time, the RAM, the memory device, and the I/O port are configured to be able to exchange data with the CPU through an internal bus. The memory device is configured by, for example, a flash memory, an HDD (Hard Disk Drive), etc. The memory device stores therein, for example, a control program for controlling the operation of the substrate processing apparatus 100, and process recipes that describe the procedure, conditions, etc., of substrate processing described later, in a readable manner. Note that the process recipes are recipes combined together so that the main controller 14 can perform the steps of a substrate processing process (described later) and a predetermined result can be obtained, and function as a program. The process recipes, control program, etc., are hereinafter also collectively simply referred to as a program. Note that when the term “program” is used in this specification, it refers to a case of including only the process recipes alone, a case of including only the control program alone, or a case of including both. Note also that the RAM is configured as a memory area (work area) that temporarily holds a program, data, etc., read by the CPU.

The main operating apparatus 16 is disposed near the substrate processing apparatus 100 (or the processing furnace 202 and the substrate processing apparatus main body 111). The main operating apparatus 16 is mounted on the substrate processing apparatus main body 111 as in this embodiment, by which the main operating apparatus 16 is fixed to the substrate processing apparatus 100 as a single unit. Here, the expression “the main operating apparatus 16 is disposed near the substrate processing apparatus 100 (or the processing furnace 202 and the substrate processing apparatus main body 111)” refers to that the main operating apparatus 16 is disposed at a position where an operator can check the state of the substrate processing apparatus 100. For example, the main operating apparatus 16 is installed in the clean room where the substrate processing apparatus main body 111 is installed. The main operating apparatus 16 includes a main display apparatus 18. The main display apparatus 18 is, for example, a liquid crystal display panel. An operation screen for operating the substrate processing apparatus 100, etc., are displayed on the main display apparatus 18. Information generated in the substrate processing apparatus 100 is displayed through an operation screen, and the displayed information can be outputted to a USB flash memory, etc., inserted into the substrate processing apparatus 100.

The sub-operating apparatus 50 includes a sub-display apparatus 52. As with the main display apparatus 18, the sub-display apparatus 52 is, for example, a liquid crystal display panel. An operation screen for operating the substrate processing apparatus 100, etc., are displayed on the sub-display apparatus 52. The operation screen displayed on the sub-display apparatus 52 has the same function as the operation screen displayed on the main display apparatus 18. Therefore, information generated in the substrate processing apparatus 100 is displayed, and the information can be outputted to a USB flash memory, etc., inserted into the substrate processing apparatus 100.

A carrying control unit 230 includes a carrying system controller 234 composed of, for example, a CPU, etc., and a processing control unit 232 includes a processing system controller 236 composed of, for example, a CPU, etc. Each of the carrying system controller 234 and the processing system controller 236 is connected to the main controller 14 through a switching hub 15. The particle counter 402 is directly connected to the main controller 14.

In addition, as illustrated in FIG. 3, a main display control unit 240 which is used, for example, to control display of the main display apparatus 18 is provided in the main operating apparatus 16. The main display control unit 240 is connected to the main controller 14 using, for example, the video cable 20.

A sub-display control unit 242 which is used, for example, to control display of the sub-display apparatus 52 is provided in the sub-operating apparatus 50. Note that the mode of the sub-display control unit 242 is not limited to that illustrated, and the sub-display control unit 242 may be connected to the main controller 14 through the communication network 40. Note also that each of the carrying system controller 234, the processing system controller 236, and the sub-display control unit 242 may be directly connected to the main controller 14 without through the switching hub 15. Note also that a sub-controller composed of, for example, a CPU, etc., may be added between the particle counter 402 and the main controller 14 so as to control the particle counter 402 and to process data from the particle counter 402.

Next, the operation of the substrate processing apparatus 100 of the present invention will be described.

As illustrated in FIGS. 1 and 2, when a pod 110 is supplied to the load port 114, the pod loading/unloading opening 112 is opened by the front shutter 113, and the pod 110 on the load port 114 is loaded into the inside of the substrate processing apparatus main body 111 from the pod loading/unloading opening 112 by the pod carrying apparatus 118.

The loaded pod 110 is automatically carried and passed to a specified shelf plate 117 of the pod shelf 105 by the pod carrying apparatus 118 and temporarily stored, and then, carried to one of the pod openers 121 from the shelf plate 117 and transferred onto a corresponding placement table 122, or directly carried to the pod opener 121 and transferred onto the placement table 122. At this time, a corresponding wafer loading/unloading opening 120 of the pod opener 121 is closed by a corresponding cap attachment/removal mechanism 123, and clean air 133 is distributed throughout the transfer chamber 124. For example, the transfer chamber 124 is filled with nitrogen gas serving as the clean air 133, by which the oxygen concentration is set to 20 ppm or less which is far lower than the oxygen concentration of the inside (atmosphere) of the substrate processing apparatus main body 111.

An opening-side end surface of the pod 110 placed on the placement table 122 is pressed against an opening edge portion of the wafer loading/unloading opening 120 of the front wall 119a of the sub-housing 119, and a cap of the pod 110 is removed by the cap attachment/removal mechanism 123, by which a wafer take-in/out opening is opened. When the pod 110 is opened by the pod opener 121, wafers 200 are picked up by the tweezers 125c of the wafer transfer apparatus 125a from the pod 110 through the wafer take-in/out opening, loaded into the standby unit 126 present at the rear of the transfer chamber 124, and charged into the boat 217. The wafer transfer apparatus 125a having passed the wafers 200 to the boat 217 returns to the pod 110 and charges the next wafers 200 into the boat 217.

During the charging operation of the wafers 200 into the boat 217 by the wafer transfer mechanism 125 using the one (top or bottom) pod opener 121, another pod 110 is carried and transferred to the other (bottom or top) pod opener 121 from the pod shelf 105 by the pod carrying apparatus 118, and the operation of opening the pod 110 by the pod opener 121 simultaneously proceeds.

When a pre-specified number of wafers 200 are charged into the boat 217, the furnace opening 301 at the lower end of the processing furnace 202 which is closed by the furnace opening shutter 147 is opened by the furnace opening shutter 147. Subsequently, by the seal cap 129 raised by the boat elevator 115, the boat 217 that holds the group of wafers 200 is loaded into the processing furnace 202.

After the loading, arbitrary processes are performed on the wafers 200 in the processing furnace 202. After the processes, the seal cap 129 is lowered by the boat elevator 115, by which the boat 217 is unloaded from within the processing furnace 202. At this time, measurement of particles is performed by the particle counter 402. After the unloading, the wafers 200 and the pod 110 are taken out of the housing by a reverse procedure to the above-described procedure up to the loading.

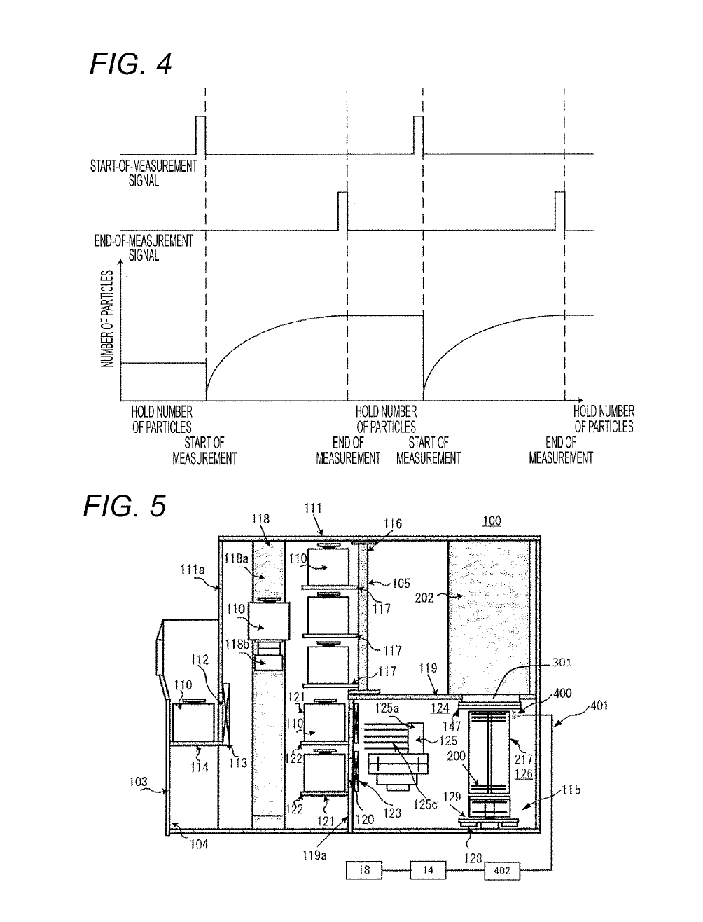

Next, a method of measuring particles by the particle counter 402 of the present invention will be described using FIG. 4. The present example describes an example using a suck type particle counter.

The particle counter 402 includes therein a pump, and sucks atmosphere around the furnace opening 301 from the particle measurement opening 400. When the boat 217 starts to go down from within the processing furnace 202, i.e., when the seal cap 129 is separated from the lower end portion of the processing furnace 202 and the furnace opening 301 is opened, the main controller 14 transmits a signal of “start of measurement” to the particle counter 402. When the particle counter 402 receives the “start of measurement” signal from the main controller 14, the particle counter 402 resets the number of particles stored before starting the measurement to 0 (zero), and then detects the number of particles contained in the sucked atmosphere, cumulatively counts the number, and records the counted number as the cumulative number of particles. In addition, the main controller 14 may display the number of particles transmitted from the particle counter 402 on the main display apparatus 18 (hereinafter, screen).

The counted number of particles is transmitted to the main controller 14 through an interface such as an analog signal or digital communication. The particle counter 402 continues the measurement of particles until receiving a signal of “end of measurement” from the main controller 14. The timing of “end of measurement” may be any timing before starting to work on the next lot, but in the present embodiment, for example, the timing is when the boat 217 has completed its going-down operation. When the particle counter 402 receives an “end of measurement” signal from the main controller 14, the particle counter 402 stops the detection of particles and stores the cumulative number of particles obtained at the end of the measurement, and transmits the cumulative number of particles to the main controller 14. The main controller 14 determines conditions in the processing furnace 202 based on the number of particles transmitted from the particle counter 402. When the main controller 14 determines that the substrate processing apparatus 100 is in an abnormal state, the main controller 14 takes predetermined measures described later.

Next, a method of determining that the substrate processing apparatus 100 is abnormal (conditions where particles occur in the processing furnace 202) and a method of taking measures after the substrate processing apparatus 100 is determined to be abnormal will be described.

First, a method of determining that the substrate processing apparatus 100 is abnormal (conditions where particles occur in the processing furnace 202) will be described.

(1) When the cumulative number of particles exceeds a preset number (limit number of particles): The main controller 14 is preset with a “limit number of particles” as a threshold value. The “limit number of particles” is the number of particles occurred when maintenance in the processing furnace 202 is required or when lot rejection caused by particles in the processing furnace 202 may possibly occur. When the cumulative number of particles which is counted cumulatively during measurement exceeds the limit number of particles, the main controller 14 determines that the substrate processing apparatus 100 is abnormal.

(2) When the amount of increase in the number of particles measured within a certain predetermined period of time after starting measurement exceeds a preset amount of increase: If particles resulting from the peeling-off of a film from a wall surface of the processing furnace 202 occur in the processing furnace 202, then many particles are emitted to the transfer chamber side from within the processing furnace 202 at the instant of opening the furnace opening 301. Hence, by detecting the amount of increase in the number of particles within a predetermined period of time after opening the furnace opening 301, the sudden occurrence of particles in the processing furnace 202 can be detected. For example, when the cumulative number of particles reaches X or more within t seconds after starting measurement, it is determined that the substrate processing apparatus 100 is abnormal. Alternatively, when the amount of increase=(Y/t) (Y is the total number of particles detected within t seconds), if this increment (gradient) per unit time is larger than a preset threshold value, it may be determined that the substrate processing apparatus 100 is abnormal.

(3) When the difference between the cumulative number of particles obtained at the end of measurement and the cumulative number of particles obtained at the end of measurement for a previous lot exceeds a preset difference number: When film formation is continuously performed under the same processing conditions and there is no particular abnormality in the state of the substrate processing apparatus 100, the numbers of particles occurring from within the processing furnace 202 for individual processes (for individual lots) are roughly the same, or gradually increase as a by-product is accumulated in the processing furnace 202. However, when there is abnormality in the state of the substrate processing apparatus 100, e.g., when the processing furnace 202 becomes cracked and a leak occurs, a large change occurs in the number of particles occurring. Hence, a difference from the cumulative number of particles obtained at the end of a previous lot process is found and the difference is managed. For example, it is assumed that the difference “Z particles” is a preset number. Assuming that the cumulative number of particles obtained at the end of previous lot measurement is X, this is stored in the main controller 14. When the cumulative number of particles for the next lot is Y (X<Y), if the difference “(Y−X) particles” is smaller than the Z particles ((Y−X)<Z), it is determined that the substrate processing apparatus 100 is normal. On the other hand, if the difference (Y−X) is the Z particles or more ((Y−X)≧Z), since the difference is too large, it is determined that the substrate processing apparatus 100 is abnormal.

By arbitrarily selecting the above-described determination methods and setting the selected method (s) on the main controller 14, a state in the processing furnace 202 can be monitored from the transfer chamber 124 side. A single determination method may be set or a plurality of determination methods may be set in combination.

Next, a method of taking measures by the substrate processing apparatus 100 after the substrate processing apparatus 100 is determined to be abnormal will be described.

(1) The substrate processing apparatus 100 only gives an alarm, and subsequent processes depend on the operator's judgment.

(2) The substrate processing apparatus 100 gives an alarm and immediately stops or temporarily stops its operation.

(3) Although the substrate processing apparatus 100 gives an alarm, the substrate processing apparatus 100 continues a process for the currently processed lot without stopping and puts wafers 200 back into a pod 110 and takes the pod 110 out after the process ends, but does not work on the next lot process. By selecting which one of these measures is to take when the substrate processing apparatus 100 is determined to be abnormal, and setting the selected measures on the main controller 14, a reduction in yield rate can be suppressed.

Note that although in the above-described example the number of particles is reset to 0 (zero) by a “start of measurement” signal, apart from the “start of measurement” signal, a “reset of measurement” signal may be provided, and with the “start of measurement” signal, counting may be performed such that the counted number is accumulated in the number counted last time without resetting the number of particles to 0 (zero), and when the “reset of measurement” signal is received, the number of particles may be reset to 0 (zero). In addition, the particle counter 402 may perform measurement at all times while the power to the apparatus 100 is turned on, and the main controller 14 may find the number of particles occurred, by storing and computing only the numbers of particles obtained at timing of “start of measurement” and “end of measurement”.

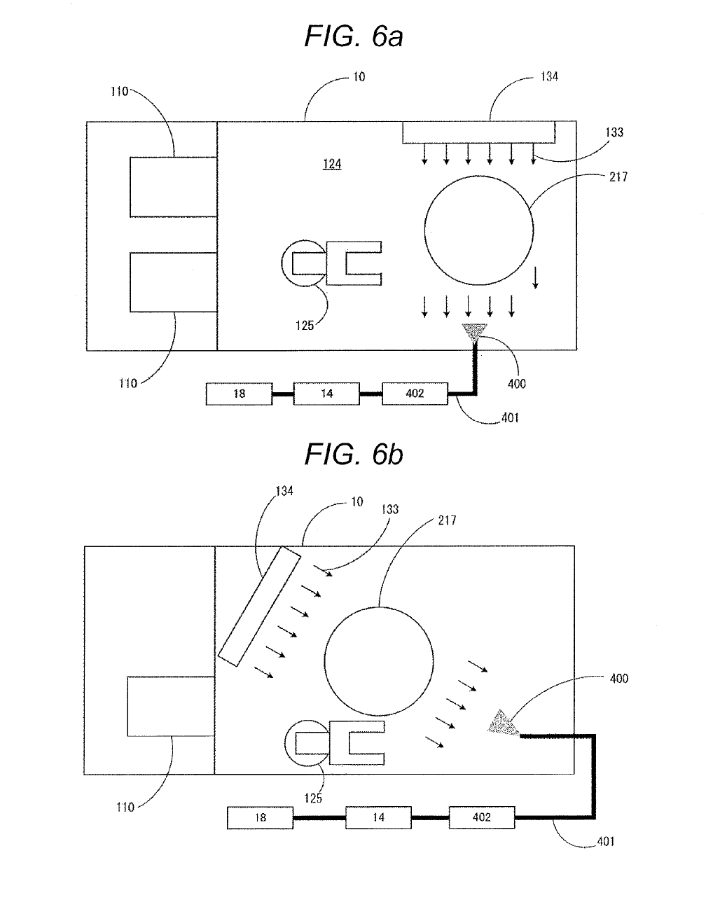

Next, a first embodiment of the installation position of a particle measurement opening 400 will be described in detail using FIGS. 5 and 6a and 6b.

In a transfer chamber 124, in order to maintain a clean environment, a clean unit 134 equipped with an air filter is installed and the atmosphere in the transfer chamber 124 is circulated. FIG. 6a illustrates a case in which a clean unit 134 is installed on a side surface of a transfer chamber 124, and FIG. 6b illustrates a case in which a clean unit 134 is installed at a corner portion of a transfer chamber 124. In order to efficiently capture particles in a processing furnace 202 coming out of a furnace opening 301 when a boat 217 is unloaded and the furnace opening 301 is opened after substrate processing, a particle measurement opening 400 is installed at a position on the opposite side of the boat 217 from the clean unit 134, preferably, a position where the air flow of clean air 133 from the clean unit 134 is in line with a furnace opening beneath area and the particle measurement opening 400, and the orientation of the opening of the particle measurement opening 400 is a direction in which the clean air 133 can be collected from the front. In addition, as illustrated in FIG. 5, it is desirable to install the particle measurement opening 400 at a height close to the furnace opening 301 which is an opening opened and closed by a furnace opening shutter 147. For example, the particle measurement opening 400 may be installed at a height position where at least apart of the particle measurement opening 400 overlaps the furnace opening shutter 147 and where interference with the furnace opening shutter 147 does not occur. In addition, for example, the particle measurement opening 400 is installed such that the extension of an opening portion of the particle measurement opening 400 perpendicularly intersects a ceiling of the transfer chamber 124. At this time, the particle measurement opening 400 may be installed such that an angle formed by the extension of the opening portion of the particle measurement opening 400 and the ceiling of the transfer chamber 124 is an acute angle so that the opening portion of the particle measurement opening 400 can be oriented in an inner-processing furnace direction. By such installation, measurement of atmosphere emitted from within the processing furnace 202 can be facilitated.

Note, however, that in a case of a high heat treatment temperature, since high-temperature atmosphere flows out of the processing furnace 202 when the furnace opening 301 is opened after processing, the temperatures of the installation area of the particle measurement opening 400 and the atmosphere sucked by a particle counter 402 become high. When the operating environment of the particle counter 402 has constraints such as an upper limit temperature by the specifications of the particle counter 402, the installation location of the particle measurement opening 400 may be set at a position away from the furnace opening 301 (a position within a temperature range where the particle counter 402 can operate). At this time, a position where particles from within the processing furnace 202 can be collected, and the orientation of the particle measurement opening 400 are determined taking into account air flow in the transfer chamber 124. For example, the particle measurement opening 400 may be installed at a position which is on the downstream side of the wind direction of the clean air 133 passing through the furnace opening beneath area, and where the particle measurement opening 400 faces the main stream of flow.

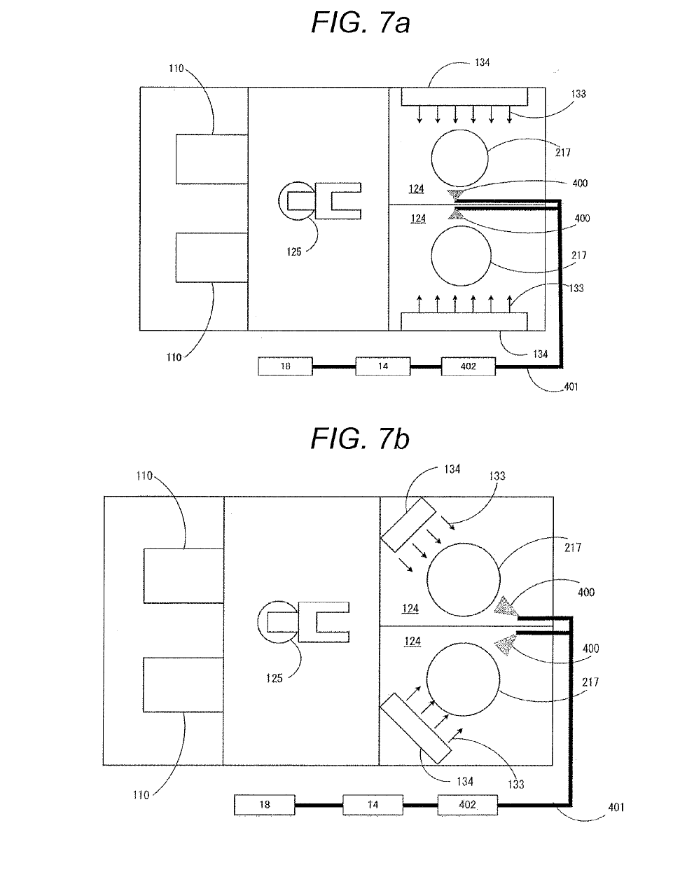

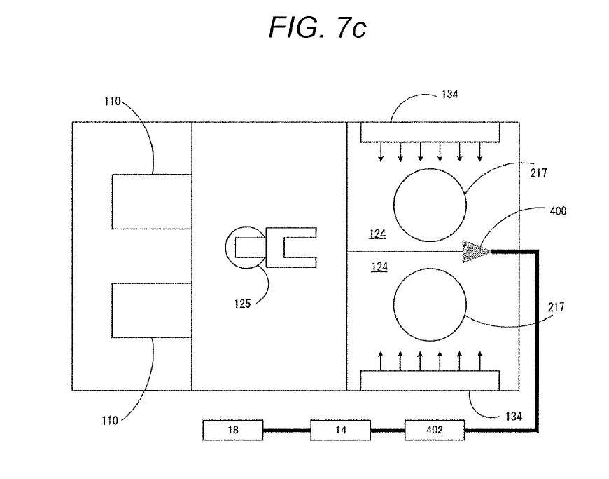

Next, a second embodiment of the installation position of a particle measurement opening 400 will be described using FIGS. 7a, 7b, and 7c. In the present embodiment, a substrate processing apparatus 100 is configured to include two transfer chambers 124.

In each transfer chamber 124, in order to maintain a clean environment, a clean unit 134 equipped with an air filter is installed and the gas in the transfer chamber 124 is circulated. FIGS. 7a and 7c illustrate a case in which the clean unit 134 is installed on a side surface of each transfer chamber 124, and FIG. 7b illustrates a case in which the clean unit 134 is installed at a corner portion of each transfer chamber 124. As in the first embodiment, in the second embodiment, too, in order to efficiently capture particles coming out of a furnace opening 301, a particle measurement opening 400 is installed at a position on the opposite side of a boat 217 from the clean unit 134, preferably, a position facing the clean unit 134 with the boat 217 interposed therebetween and beneath the furnace opening 301 in each transfer chamber 124.

In addition, as illustrated in FIG. 7c, one particle counter 402 may be installed at a central position of the two transfer chambers 124. For example, a hole that communicates between the two transfer chambers 124 for installing the particle counter 402 is made in a wall that separates the two transfer chambers 124. By such a configuration, even when the substrate processing apparatus 100 has two transfer chambers, measurement can be handled by a single particle counter 402. Two processing furnaces 202 do not simultaneously end their processes and perform their processes alternately. For example, by mounting the particle counter 402 on a particle counter moving mechanism, the particle measurement opening 400 may be oriented toward a target transfer chamber side only when detecting particles.

By the present invention, one or a plurality of effects shown below are provided.

1. Productivity can be Improved.

Conventional operation is such that a preset number of lots are processed and then cleaning is performed, and the number of lots is set with some allowance. On the other hand, according to the present invention, by detecting the number of particles for each lot, conditions in a processing furnace can be monitored, and thus, cleaning, etc., can be performed at appropriate timing. By this, apparatus operating time can be extended over conventional apparatuses, enabling to improve productivity.

2. Even when Lot Rejection Occurs, Damage can be Minimized.

Conventionally, substrates are processed and then the amounts of particles on the substrates are measured by a substrate surface inspection apparatus. Hence, even after the occurrence of lot rejection, during a period before results come out by inspecting substrates for a lot where the lot rejection occurs, a process for the next lot starts, resulting in an increase in the number of substrates with lot rejection. However, by detecting, in a substrate processing apparatus, the conditions of the occurrence of particles, the occurrence of lot rejection can be detected upon unloading of a boat and thus can be handled before unloading substrates and moving to the next lot, enabling to minimize damage caused by lot rejection.

3. While in a Transfer Chamber, Conditions in a Processing Chamber can be Monitored.

Upon processing substrates in a processing chamber, when a boat goes up, an entrance (furnace opening) to the processing chamber is covered by a seal cap, and thus, the inside of the processing chamber and a transfer chamber form a partitioned space. When substrates are processed in the processing chamber, a film or a by-product is adhered in the processing chamber, which becomes a cause of particles. That is, when the boat is lowered and the furnace opening opens after substrate processing, particles in the processing chamber come out to the transfer chamber. Due to this characteristic, by installing a particle counter near the furnace opening, particles in a substrate processing furnace coming out of the furnace opening can be securely collected. In addition, due to the fact that particles originated from a driving unit in the transfer chamber are heavy and thus deposited near the bottom of a substrate processing apparatus, particles originated from the transfer chamber and particles originated from the processing furnace can be detected separately. Thus, while in the transfer chamber, conditions in the processing chamber can be monitored.

4. Operation can be Performed at Low Cost.

To directly monitor the inside of a processing furnace whose environment changes a lot, a detection apparatus requires high durability, or a design change/complication of an apparatus such as installation of a window near a processing chamber become necessitated. However, according to the present invention, monitoring of the inside of the processing furnace can be performed only by installing a particle counter in a transfer chamber, monitoring of the inside of the processing chamber can be performed at low cost and with a simple configuration.

Film formation performed by the substrate processing apparatus 100 includes, for example, the processes of forming an oxide film and a nitride film and the process of forming a film containing metal, in addition to CVD, PVD, ALD, and Epi. Furthermore, processes such as annealing, oxidizing, and diffusion may be performed.

In addition, although the embodiments describe that a substrate processing apparatus is a vertical processing apparatus 100, the present invention can also be applied to a single-wafer apparatus in the same manner. Furthermore, the present invention can also be applied to an etching apparatus, an exposure apparatus, a lithography apparatus, a coating apparatus, a molding apparatus, a development apparatus, a dicing apparatus, a wire bonding apparatus, an inspection apparatus, etc., in the same manner.

In addition, the present invention can also be applied to a group management apparatus (management server) that is connected to a plurality of substrate processing apparatuses 100 through a communication line and that manages the states of the plurality of substrate processing apparatuses 100, and to a substrate processing system that includes such substrate processing apparatuses and group management apparatus. Note that the group management apparatus does not need to be disposed on the same floor (clean room) as the substrate processing apparatuses, and may be, for example, LAN connected and disposed in an office. In addition, in the group management apparatus, a storage unit (database), a control unit, an operating unit, and a display unit do not need to be formed into a single unit and may be different units, and a configuration may be such that remote operations on an operation screen (e.g., an installation operation, etc.) by a terminal apparatus disposed in an office can be performed on data in the database disposed in the clean room.

Note that the above-described program may be, for example, a program recorded on a non-transitory computer-readable recording medium such as a computer readable hard disk, flexible disk, or compact disc, and installed on a system's control unit from the recording medium.

Note that this application claims the benefit of priority to Japanese Patent Application No. 2014-032949, filed Feb. 24, 2014, the disclosure of which is hereby incorporated by reference in its entirely.

### INDUSTRIAL APPLICABILITY

According to the present invention, conditions in a processing furnace can be monitored and a reduction in yield rate caused by particles occurring in the processing furnace can be suppressed.

### REFERENCE SIGNS LIST

100: SUBSTRATE PROCESSING APPARATUS
14: MAIN CONTROLLER
134: CLEAN UNIT
147: FURNACE OPENING SHUTTER
200: WAFER (SUBSTRATE)
202: PROCESSING FURNACE
217: BOAT
301: FURNACE OPENING

1. A substrate processing apparatus comprising:
a transfer chamber including a gas supply mechanism on a side surface thereof and configured to transfer a substrate to a substrate holder;
a processing furnace configured to process the substrate bolded in the substrate holder;
a furnace opening that communicates between the transfer chamber and the processing furnace;
a cap having the substrate holder placed thereon and configured to close the furnace opening;
a raising/lowering mechanism configured to raise and lower the cap;
a measurer installed at a position facing the gas supply mechanism in the transfer chamber with the substrate holder interposed therebetween, and configured to count a number of particles at the furnace opening; and
a control unit configured to control the raising/lowering mechanism and the measurer so as to start measurement of a number of particles by the measurer when the furnace opening is opened.

2. The substrate processing apparatus according to claim 1, wherein the control unit is configured to control the measurer so as to continue the measurement for a predetermined period of time after the furnace opening is opened.

3. The substrate processing apparatus according to claim 2, wherein the control unit is configured to control the measurer so as to cumulatively store a number of particles counted during the predetermined period of time and transmit the number of particles to the control unit.

4. The substrate processing apparatus according to claim 3, wherein the control unit is configured to determine conditions in the processing furnace, based on the number of particles counted by the measurer.

5. The substrate processing apparatus according to claim 4, wherein the control unit is configured to determine that the apparatus is abnormal when the cumulative number of particles counted during the predetermined period of time exceeds a predetermined threshold value set in advance.

6. The substrate processing apparatus according to claim 4, wherein the control unit is configured to determine that the apparatus is abnormal when a number of particles increased per unit time during the measurement exceeds a predetermined threshold value set in advance.

7. The substrate processing apparatus according to claim 4, wherein the control unit is configured to determine that the apparatus is abnormal when a difference between a cumulative number of particles obtained at an end of measurement and a cumulative number of particles obtained at a previous process exceeds a predetermined threshold value set in advance.

8. The substrate processing apparatus according to claim 4, wherein the control unit is configured to give an alarm when the apparatus is determined to be abnormal.

9. The substrate processing apparatus according to claim 1, further comprising a furnace opening's opening/closing mechanism configured to open and close the furnace opening, wherein
the measurer is installed at a height position where at least apart of the measurer overlaps the furnace opening's opening/closing mechanism.

10. The substrate processing apparatus according to claim 1, wherein the control unit is configured to record the number of particles for each lot.

11. A substrate processing apparatus comprising:
a transfer chamber including a gas supply mechanism on a side surface thereof and configured to transfer a substrate to a substrate holder on a cap;
a processing furnace configured to process the substrate bolded in the substrate holder;
a furnace opening that communicates between the transfer chamber and the processing furnace;
a raising/lowering mechanism configured to raise and lower the cap; and
a measurer installed near the furnace opening and installed at a position facing the gas supply mechanism in the transfer chamber with the substrate holder interposed therebetween.
